(19) United States
(12) Patent Application Publication
(10) Pub. No.: US 2006/0094171 A1
(43) Pub. Date: May 4, 2006

(54) Isolation trench thermal annealing method for non-bulk silicon semiconductor substrate

(75) Inventor: Jhon Jhy Liaw, Hsin-Chu (TW)

Correspondence Address: TUNG & ASSOCIATES, Suite 120, 838 W. Long Lake Road, Bloomfield Hills, MI, 48302, US

(73) Assignee: Taiwan Semiconductor Manufacturing Co., Ltd.

(21) Appl. No.: 10/982,456

(22) Filed: Nov. 4, 2004

(51) Int. Cl. H01L 21/76; H01L 21/336

(52) U.S. Cl. 438/149; 438/424; 438/296

(57) ABSTRACT

A method for fabricating a semiconductor product employs a semiconductor substrate other than a bulk silicon semiconductor substrate. The semiconductor substrate is etched to form an etched semiconductor substrate having an isolation trench adjoining an active region. The etched semiconductor substrate is thermally annealed prior to forming a semiconductor device within the active region.

### BACKGROUND OF THE INVENTION

1. Field of the Invention

The invention relates generally to methods for fabricating semiconductor products. More particularly, the invention relates to methods for fabricating semiconductor products with enhanced performance.

2. Description of the Related Art

As semiconductor technology has advanced, the use of semiconductor substrates other than bulk silicon semiconductor substrates has increased. Prevalent alternative semiconductor substrates include silicon-germanium alloy semiconductor substrates, compound semiconductor substrates (including gallium arsenide semiconductor substrates) and silicon-on-insulator (SOI) semiconductor substrates. The foregoing alternative semiconductor substrates are generally desirable when fabricating semiconductor products insofar as they often provide for enhanced performance of semiconductor devices fabricated therein.

Notwithstanding such enhanced performance, the alternative semiconductor substrates may nonetheless still be prone to defects when fabricating semiconductor products therefrom. Since defects typically negatively influence semiconductor product performance and yield, mitigation of defects is thus desirable when fabricating semiconductor products.

It is thus desirable to fabricate semiconductor products while employing semiconductor substrates other than bulk silicon semiconductor substrates, and while minimizing defects. The invention is directed towards the foregoing object.

### SUMMARY OF THE INVENTION

A first object of the invention is to provide a method for fabricating a semiconductor product while employing other than a bulk silicon semiconductor substrate.

A second object of the invention is to provide a method in accord with the first object of the invention, where defects are minimized when fabricating the semiconductor product while employing other than the bulk silicon semiconductor substrate.

In accord with the objects of the invention, the invention provides a method for fabricating a semiconductor product. The method first provides a semiconductor substrate other than a bulk silicon semiconductor substrate. The semiconductor substrate is etched to form an isolation trench adjoining an active region within an etched semiconductor substrate. Finally, the etched semiconductor substrate is thermally annealed prior to forming a semiconductor device within the active region.

The invention contemplates various combinations of thermal annealing atmospheres within the context of various semiconductor substrates other than bulk silicon semiconductor substrates.

The invention provides a method for fabricating a semiconductor product while employing a semiconductor substrate other than a bulk silicon semiconductor substrate, where defects are minimized when fabricating the semiconductor product.

The invention realizes the foregoing object within the context of thermally annealing an etched semiconductor substrate other than a bulk silicon semiconductor substrate. The etched semiconductor substrate has an isolation trench and adjoining active region formed therein. The etched semiconductor substrate is thermally annealed prior to forming a semiconductor device within the active region.

### BRIEF DESCRIPTION OF THE DRAWINGS

The objects, features and advantages of the invention are understood within the context of the Description of the Preferred Embodiment, as set forth below. The Description of the Preferred Embodiment is understood within the context of the accompanying drawings, which form a material part of this disclosure, wherein:

FIG. 1 to FIG. 8 show a series of schematic cross-sectional diagrams illustrating the results of progressive stages of fabricating a semiconductor product in accord with a preferred embodiment of the invention.

### DESCRIPTION OF THE PREFERRED EMBODIMENT

The invention provides a method for fabricating a semiconductor product while employing other than a bulk silicon semiconductor substrate, where defects are minimized when fabricating the semiconductor product.

The invention realizes the foregoing object within the context of thermally annealing an etched semiconductor substrate other than a bulk silicon semiconductor substrate. The etched semiconductor substrate has an isolation trench and adjoining active region formed therein. The etched semiconductor substrate is thermally annealed prior to forming a semiconductor device within the active region.

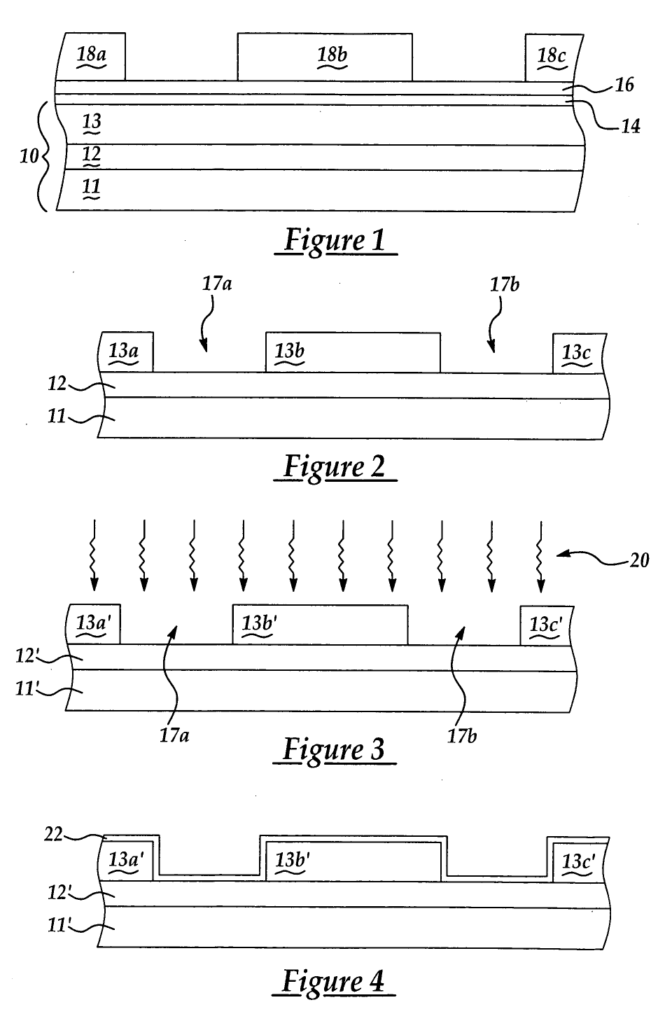

FIG. 1 to FIG. 8 show a series of schematic cross-sectional diagrams illustrating the results of progressive stages in fabricating a semiconductor product in accord with a preferred embodiment of the invention.

FIG. 1 shows a semiconductor substrate other than a bulk silicon semiconductor substrate 10. The semiconductor substrate other than a bulk silicon semiconductor substrate 10 may comprise any of several semiconductor materials other than solely a bulk silicon semiconductor material (which is intended to also include a bulk silicon semiconductor material having a silicon epitaxial layer formed thereupon). Such semiconductor materials other than solely a bulk silicon semiconductor material may include, but are not limited to: (1) silicon-germanium alloy semiconductor materials; (2) gallium arsenide (and other compound semiconductor) materials; and (3) semiconductor-on-insulator semiconductor materials (such as silicon-on-insulator (SOI) semiconductor materials, silicon-germanium alloy-on-insulator semiconductor materials and compound semiconductor-on-insulator semiconductor materials).

FIG. 1 more particularly illustrates a semiconductor-on-insulator semiconductor substrate for the semiconductor substrate other than a bulk silicon semiconductor substrate 10. The invention is not, however, so limited. The semiconductor-on-insulator semiconductor substrate is more particularly a silicon-on-insulator (SOI) semiconductor substrate. Such a semiconductor-on-insulator semiconductor substrate typically comprises: (1) a bulk substrate 11; (2) a blanket buried dielectric layer 12; and (3) a blanket semiconductor surface layer 13. Although the bulk substrate 11 may comprise any of several substrates, the bulk substrate 11 is typically a bulk silicon semiconductor substrate. In addition, although the blanket buried dielectric layer 12 may comprise any of several dielectric materials, such as but not limited to silicon oxide dielectric materials, silicon nitride dielectric materials and silicon oxynitride dielectric materials, the blanket buried dielectric layer 13 is typically formed of a silicon oxide dielectric material. The blanket buried dielectric layer 12 is typically formed to a thickness of from about 200 to about 200000 angstroms. The blanket semiconductor surface layer 13 may be formed of semiconductor materials including but not limited to silicon semiconductor materials, silicon-germanium alloy semiconductor materials and compound semiconductor materials, but most typically silicon semiconductor materials within the context of a silicon-on-insulator (SOI) semiconductor substrate. Typically, the blanket semiconductor surface layer 13 is formed to a thickness of from about 50 to about 50000 angstroms.

FIG. 1 also illustrates: (1) a blanket pad dielectric layer 14 formed upon the blanket semiconductor surface layer 13; (2) a blanket silicon nitride layer 16 formed upon the blanket pad dielectric layer 14; and (3) a series of patterned photoresist layers 18a, 18b and 18c formed upon the blanket silicon nitride layer 16.

The blanket pad dielectric layer 14 is typically formed of a silicon oxide material when the blanket semiconductor surface layer 13 is formed of a silicon semiconductor material. The blanket pad dielectric layer 14 is typically formed to a thickness of from about 30 to about 500 angstroms and typically formed employing a thermal oxidation method. Alternative thicknesses and methods may also be employed for forming the blanket pad dielectric layer 14. The blanket silicon nitride layer 16 is formed of a silicon nitride material typically formed to a thickness of from about 100 to about 2000 angstroms and deposited employing a chemical vapor deposition (CVD) method. Alternative thicknesses and methods may also be employed.

Each of the series of patterned photoresist layers 18a, 18b and 18c is formed to a thickness of from about 1000 to about 20000 angstroms and may be formed employing photoresist materials including but not limited to positive photoresist materials and negative photoresist materials.

FIG. 2 shows the results of: (1) sequentially patterning the blanket silicon nitride layer 16, the blanket pad dielectric layer 14 and the and the blanket semiconductor surface layer 13, while employing the series of patterned photoresist layers 18a, 18b and 18c as a mask and the blanket buried dielectric layer 12 as an etch stop layer; and (2) subsequently stripping the series of patterned photoresist layers 18a, 18b and 18c, and a corresponding series of patterned silicon nitride layers and series of patterned pad oxide layers from a series of patterned semiconductor surface layers 13a, 13b and 13c. The resulting series of patterned silicon surface layers 13a, 13b and 13c laterally defines a pair of isolation trenches 17a and 17b. The blanket buried dielectric layer 12 defines a pair of floors of the pair of isolation trenches 17a and 17b.

FIG. 3 first shows the results of thermally annealing the semiconductor product of FIG. 2 with a first thermal annealing treatment 20. The first thermal annealing treatment 20 forms a series of once thermally annealed patterned semiconductor surface layers 13a′, 13b′ and 13c′ formed upon a once thermally annealed blanket buried dielectric layer 12′ in turn formed upon a once thermally annealed substrate 11′.

The first thermal annealing treatment 20 may employ inert gases (such as argon and helium), nitriding gases (such as nitrogen), oxidizing gases (such as oxygen and ozone), reducing gases (such as hydrogen), multiply reactive gases such as moisture, nitric oxide, nitrous oxide, ammonia and hydrazine) and mixtures thereof. The first thermal annealing treatment 10 may also be provided employing any of several thermal annealing methods, including but not limited to furnace annealing methods, rapid thermal annealing (RTA) methods, spike annealing methods, laser annealing methods and coherent light irradiation annealing methods. The foregoing thermal annealing methods are intended to provide a thermal annealing temperature of from about 400 to about 1500 degrees centigrade for a time period of from about one second to about one hour, with the exception of furnace annealing methods which are intended to provide a thermal annealing temperature of from about 400 to about 1300 degrees centigrade for a time period of from about 1 minute to about 24 hours. The thermal annealing methods may be provided at sub-atmospheric pressure (as low as about 10 torr), atmospheric pressure and super-atmospheric pressure (as high as about 10 atmospheres). The first thermal annealing treatment 20 may employ multiple sequential temperature excursions and reversions.

FIG. 4 shows the results of forming a blanket dielectric liner layer 22 upon the once thermally annealed semiconductor product of FIG. 3. The blanket dielectric liner layer 22 is typically formed of a silicon oxide material and may be formed employing a thermal annealing method, although such is not specifically illustrated within the schematic cross-sectional diagram of FIG. 4 nor particularly required within the invention. Typically, the blanket dielectric liner layer 22 is formed to a thickness of from about 20 to about 300 angstroms.

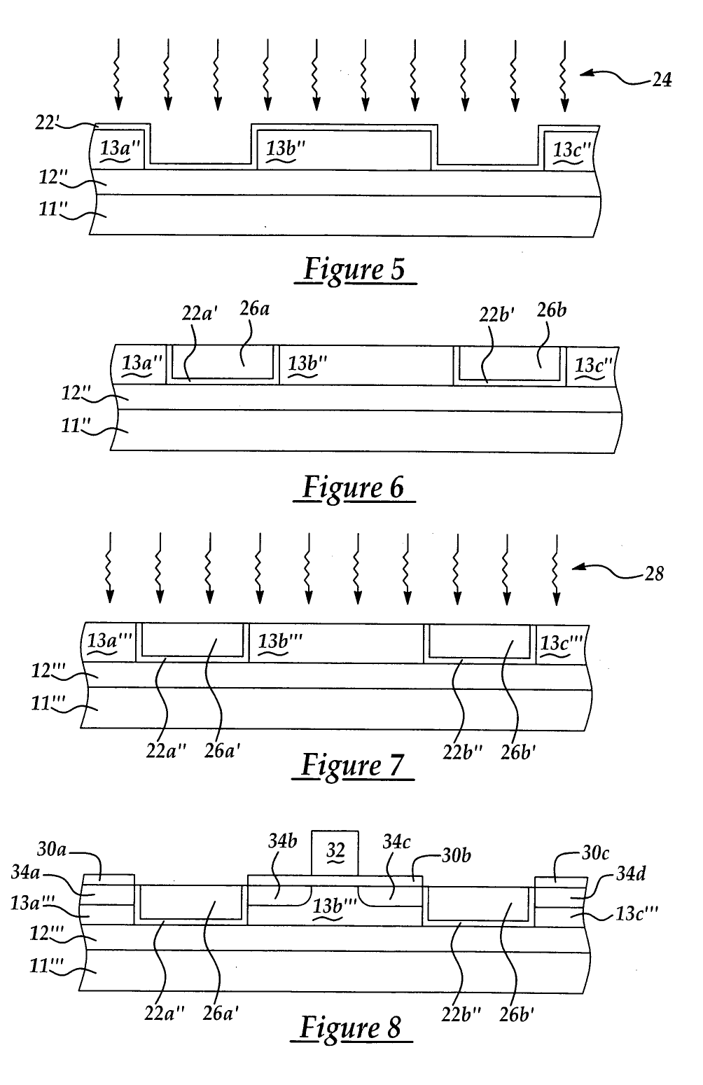

FIG. 5 shows the results of thermally annealing the semiconductor product of FIG. 4 with a second thermal annealing treatment 24. The second thermal annealing treatment 24 provides: (1) a once thermally annealed blanket dielectric liner layer 22′ formed upon; (2) a series of twice thermally annealed patterned semiconductor surface layers 13a″, 13b″ and 13c″, formed upon (3) a twice thermally annealed blanket buried dielectric layer 12″, formed upon; (4) a twice thermally annealed substrate 11″.

The second thermal annealing treatment 24 may be provided employing methods, materials and conditions otherwise analogous, equivalent or identical to the methods, materials and conditions employed for providing the first thermal annealing treatment 20.

FIG. 6 shows the results of forming a pair of isolation regions 26a and 26b within the pair of isolation trenches 17a and 17b. The pair of isolation regions 26a and 26b is formed upon a pair of once thermally annealed patterned dielectric liner layers 22a′ and 22b′ that are also formed within the pair of isolation trenches 17a and 17b. The foregoing isolation regions and patterned dielectric liner layers are typically formed employing a planarizing method, such as a chemical mechanical polish (CMP) planarizing method.

FIG. 7 shows the results of further thermally annealing the semiconductor product of FIG. 6 with a third thermal annealing treatment 28.

The third thermal annealing treatment 28 provides: (1) a pair of once thermally annealed isolation regions 26a′ and 26b′ formed upon; (2) a pair of twice thermally annealed patterned dielectric liner layers 22a″ and 22b″ both formed within a pair of isolation trenches 17a and 17b laterally defined by; (3) a series of three times thermally annealed patterned semiconductor surface layers 13a′″, 13b′″ and 13c′″, in turn formed upon; (4) a three times thermally annealed blanket buried dielectric layer 12′″, finally in turn formed upon; (5) a three times thermally annealed substrate 11′″.

The third thermal annealing treatment 28 may be provided employing methods, materials and conditions analogous, equivalent or identical to the methods, materials and conditions employed for providing the first thermal annealing treatment 20 and the second thermal annealing treatment 24.

FIG. 8 shows the results of forming within the active region of the three times thermally annealed patterned semiconductor surface layer 13b′″ a field effect transistor (FET) device. The field effect transistor (FET) device comprises: (1) a gate dielectric layer 30b formed upon the three times thermally annealed patterned semiconductor surface layer 13b′″; (2) a gate electrode 32 formed thereupon; and (3) a pair of source/drain regions 34b/34c formed within the three times thermally annealed patterned semiconductor surface layer 13b″″ and separated by the gate electrode 32. Also illustrated are two additional gate dielectric layers 30a/30c formed upon the corresponding three times thermally annealed patterned semiconductor surface layers 13a′″ and 13c′″, and a pair of source/drain regions 34a and 34d additionally formed therein.

FIG. 8 shows a semiconductor product fabricated in accord with a preferred embodiment of the invention. The semiconductor product is formed from a semiconductor substrate other that a bulk silicon semiconductor substrate. An active region and an adjoining isolation trench are formed within the semiconductor substrate to provide an etched semiconductor substrate. The etched semiconductor substrate is thermally annealed after forming the isolation trench therein but before forming a semiconductor device within the active region. The preferred embodiment of the invention illustrates three separate processing sequences where a thermal annealing treatment may be incorporated within the context of the invention (i.e., after forming an isolation trench, after forming a liner layer within the isolation trench and after forming an isolation region within the isolation trench). The invention is not limited to employing all three of the foregoing thermal annealing treatments, but rather any one, two or all three of the thermal annealing treatments may be employed. Preferably, the invention employs at least one of the first thermal treatment and the second thermal treatment and may omit the third thermal treatment such that thermal annealing of sidewall and floor surfaces of an isolation trench may be effected absent impediment of an isolation region formed within the isolation trench. Incident to at least one thermal treatment in accord with the invention, a semiconductor device formed within an active region adjoining an isolation trench is formed with enhanced performance. While not wishing to be bound by any particular theory, it is believed that the annealing provides defect and roughness reduction for an interior of an isolation trench (and particularly an interior sidewall and corner of the isolation trench). The defect and roughness reduction in turn provides for enhanced semiconductor device performance.

The preferred embodiment of the invention is illustrative of the invention rather than limiting of the invention. Revisions and modifications may be made to a semiconductor product in accord with the preferred embodiment of the invention while still providing a semiconductor product in accord with the invention, further in accord with the accompanying claims.

What is claimed is:

1. A method for fabricating a semiconductor product comprising:
providing a semiconductor substrate other than a bulk silicon semiconductor substrate;
etching the semiconductor substrate to form an isolation trench adjoining an active region within an etched semiconductor substrate;
annealing thermally the etched semiconductor substrate prior to forming a semiconductor device within the active region.

2. The method of claim 1 wherein the etched semiconductor substrate is also thermally annealed prior to forming an isolation region within the isolation trench.

3. The method of claim 1 wherein the thermal annealing is a furnace thermal annealing.

4. The method of claim 1 wherein the thermal annealing is a rapid thermal annealing.

5. The method of claim 1 wherein the thermal annealing is undertaken in a nitrogen atmosphere.

6. The method of claim 1 wherein the thermal annealing is undertaken in an oxidizing atmosphere.

7. The method of claim 1 wherein the thermal annealing is undertaken in a mixed reactive gas atmosphere.

8. The method of claim 1 wherein the thermal annealing is undertaken at a single process step when fabricating the semiconductor product.

9. The method of claim 1 wherein the thermal annealing is undertaken at multiple process steps when fabricating the semiconductor product.

10. The method of claim 1 wherein the thermal annealing is undertaken for multiple repetitive cycles within a single thermal annealing process step.

11. A method for fabricating a semiconductor product comprising:
providing a semiconductor on insulator semiconductor substrate;
etching the semiconductor substrate to form an isolation trench adjoining an active region within an etched semiconductor substrate;
annealing thermally the etched semiconductor substrate prior to forming a semiconductor device within the active region.

12. The method of claim 11 wherein the semiconductor on insulator semiconductor substrate is selected from the group consisting of silicon on insulator (SOI) semiconductor substrates, silicon-germanium on insulator semiconductor substrates and compound semiconductor on insulator semiconductor substrates.

13. The method of claim 11 wherein the thermal annealing is a furnace thermal annealing.

14. The method of claim 11 wherein the thermal annealing is a rapid thermal annealing.

15. The method of claim 11 wherein the thermal annealing is undertaken in a nitrogen atmosphere.

16. The method of claim 11 wherein the thermal annealing is undertaken in an oxidizing atmosphere.

17. The method of claim 11 wherein the thermal annealing is undertaken in a mixed reactive gas atmosphere.

18. The method of claim 11 wherein the thermal annealing is undertaken in a single process step when fabricating the semiconductor substrate.

19. The method of claim 11 wherein the thermal annealing is undertaken at multiple process steps when fabricating the semiconductor substrate.

20. The method of claim 11 wherein the thermal annealing is undertaken for multiple repetitive cycles within a single thermal annealing process step.

21. A method of fabricating a semiconductor product comprising:
applying a mask layer to an active layer;
patterning the mask layer to expose areas of the active layer;
etching the exposed areas of the active layer; and
annealing exposed areas of the active layer.

22. The method of claim 21 wherein the active layer is an active layer of a silicon-on-insulator wafer.

23. The material of claim 22 wherein the active layer is from a group consisting of Si, SiGe, GaAs, and combinations thereof.

24. The method of claim 21 wherein the mask layer comprises a material selected from the group consisting of oxide, silicon dioxide, silicon nitride, silicon oxynitride, high-K dielectric, and combinations thereof.

25. The method of claim 21 wherein the step of annealing is performed at a temperature between about 500° C. and about 1250° C.

26. The method of claim 16 wherein the step of annealing is performed in an ambient comprising N₂, O₂, H₂O, NO, or combinations thereof.

27. The method of claim 21 wherein the step of annealing produces an oxidation layer between about 25 Å and about 200 Å in thickness.
